(19) United States
(12) Patent Application Publication
(10) Pub. No.: US 2026/0163335 A1
(43) Pub. Date: Jun. 11, 2026

(54) SEMICONDUCTOR LASER ELEMENT AND LIGHT-EMITTING DEVICE

(71) Applicant: Quanzhou sanan semiconductor technology Co., Ltd., Fujian (CN)

(72) Inventors: Tungwei YEN, Fujian (CN); Yushou WANG, Fujian (CN); Shaohua HUANG, Fujian (CN); Chungying CHANG, Fujian (CN)

(73) Assignee: Quanzhou sanan semiconductor technology Co., Ltd., Fujian (CN)

(21) Appl. No.: 19/415,558

(22) Filed: Dec. 10, 2025

(30) Foreign Application Priority Data
Dec. 11, 2024 (CN) 202411820034.5

(51) Int. Cl. H01S 5/30; H01S 5/22

(52) U.S. Cl. CPC H01S 5/3054; H01S 5/2205; H01S 5/3077

(57) ABSTRACT

Provided are a semiconductor laser element and a light-emitting device. An electron barrier layer is disposed between a second coating layer and a second wave guide layer of the semiconductor laser element. The second semiconductor layer is doped with a P-type dopant having at least one doping concentration peak in the electron barrier layer. The Mg doping concentration at the doping concentration peak is less than the maximum doping concentration of the P-type dopant in the second semiconductor layer. In a direction gradually approaching the electron barrier layer, the doping concentration of the P-type dopant in the second coating layer has multiple partitions, a curve of the P-type dopant doping concentration decreases partition by partition along multiple partitions. Disposing the second semiconductor layer reduces absorption of light and improves a light exit effect of the device.

### CROSS-REFERENCE TO RELATED APPLICATION

This application claims the priority benefit of Chinese application serial no. 202411820034.5, filed on Dec. 11, 2024. The entirety of the above-mentioned patent application is hereby incorporated by reference herein and made a part of this specification.

### BACKGROUND

### Technical Field

This disclosure relates to semiconductor manufacturing technology, and in particular to a semiconductor laser element and a light-emitting device.

### Related Art

Group III nitrides represented by gallium nitride are direct transition wide bandgap semiconductor materials, which have wide energy bands and are ideal materials for manufacturing laser devices from ultraviolet to green light wavelengths. Gallium nitride-based blue-green light of laser devices have advantages of small size, high integration, high brightness, and high resolution. The distribution of optical field and photon confinement capability are key factors affecting the performance of gallium nitride-based blue-green light of the laser devices.

In the laser devices, P-type semiconductor layers are usually doped with an Mg element. The doping and diffusion of Mg concentration may generate unnecessary optical absorption phenomena, affecting the photoelectric efficiency (carrier injection) of the laser devices. Meanwhile, when the laser devices are under high temperature and high current density for a long time, the Mg diffusion may cause damage to anti-reflective (AR) cavity surfaces, and may also cause catastrophic optical damage (COD) in the laser devices, which thereby leads to performance degradation of the laser devices and affects the reliability of the laser devices.

Therefore, how to reduce unnecessary optical absorption caused by doping while ensuring sufficient carriers for effective carrier recombination is necessary.

Given the defects and deficiencies existing in the prior art, the disclosure provides a semiconductor laser element and light-emitting device to solve one or more of the aforementioned problems.

### SUMMARY

According to an aspect of the disclosure, provided is a semiconductor laser element including a semiconductor stack. The semiconductor stack includes a first semiconductor layer, a first wave guide layer, an active layer, a second wave guide layer, and a second semiconductor layer stacked sequentially from bottom to top. The first semiconductor layer is an N-type doped layer. The second semiconductor layer is a P-type doped layer. In a direction away from the active layer, the second semiconductor layer is sequentially provided with an electron barrier layer and a second coating layer. In the electron barrier layer, a P-type dopant has at least one doping concentration peak. A doping concentration of the P-type dopant at the doping concentration peak is less than the maximum doping concentration of the P-type dopant in the second semiconductor layer. In a direction gradually approaching the electron barrier layer, a doping concentration of the P-type dopant in the second coating layer has multiple partitions. A doping concentration curve of the P-type dopant decreases partition by partition along the partitions.

According to an aspect of the disclosure, the disclosure also provides a light-emitting device. The light-emitting device includes the semiconductor laser element described in the aforementioned technical solution.

Compared with the prior art, the semiconductor laser element and light-emitting device provided by the disclosure have at least the following beneficial effects. In the technical solution of the disclosure, an electron barrier layer is provided between the second coating layer and the second wave guide layer of the semiconductor laser element. The second semiconductor layer is doped with a P-type dopant. A P-type dopant in the electron barrier layer has at least one doping concentration peak. The Mg doping concentration at the doping concentration peak is less than the maximum doping concentration of the P-type dopant in the second semiconductor layer. In a direction gradually approaching the electron barrier layer, the doping concentration of the P-type dopant in the second coating layer has multiple partitions. A doping concentration curve of the P-type dopant has different decreasing trends within the partitions. Disposing a decreasing trend of the Mg doping concentration in the second semiconductor layer may ensure that the second semiconductor layer provides sufficient holes, improves hole injection efficiency in quantum well layers, and improves light-emitting efficiency. Meanwhile, disposing the second semiconductor layer may reduce absorption of light and improve a light exit effect of the device.

Additionally, in the direction gradually approaching the electron barrier layer, the doping concentration of the P-type dopant in the second coating layer has the partitions. Doping concentration curves of the P-type dopant of the partitions have different change trends, that is, different slopes. For example, in the direction gradually approaching the electron barrier layer, the doping concentration of the P-type dopant in the second coating layer sequentially has a fourth partition, a third partition, a second partition, and a first partition. The first partition has the minimum slope value. The fourth partition has the maximum slope value. A slope value of the second partition is greater than a slope value of the third partition. In the third partition, an Mg concentration range and a concentration decreasing trend are controlled to reduce the impedance of series resistance of the light-emitting diode. Meanwhile, there is a probability to activate more Mg to provide more holes and improve the hole injection efficiency of the quantum well in the active layer.

In some embodiments, a thickness of the first partition is controlled to be less than a thickness of the second partition, and also less than a thickness of the third partition. Thereby, the injection depth of holes is controlled to improve hole injection efficiency, and further improve electron-hole recombination efficiency. Appropriately increasing the thicknesses of the second partition and the third partition is beneficial to improving the process of manufacturing the ridge in the laser diode.

Additionally, the light-emitting device provided by the disclosure includes the semiconductor laser element provided by the aforementioned technical solution. Therefore, the light-emitting device also has the aforementioned good technical effects.

### BRIEF DESCRIPTION OF THE DRAWINGS

In order to more clearly illustrate the technical solutions in the embodiments of the disclosure or the prior art, the drawings required for use in the description of the embodiments or the prior art are briefly described in the following. Obviously, the drawings in the following description are some embodiments of the disclosure. For those skilled in the art, other drawings may also be obtained based on these drawings without creative effort. In the following description, the positional relationships described in the drawings, unless specifically indicated, are all based on the direction in which the components are illustrated in the figures.

For convenience or clarity, the thickness and dimensions of each layer shown in the figures may be exaggerated, omitted, or schematically drawn. Additionally, the dimensions of the light-emitting device do not completely reflect actual dimensions.

FIG. 1 shows a schematic cross-sectional structural diagram of a semiconductor laser element according to Embodiment 1 of the disclosure.

FIG. 2 shows a relationship diagram of doping concentration, ion intensity, and depth of partial elements of the semiconductor laser element provided by Embodiment 1.

FIG. 3 shows a locally enlarged schematic diagram of a portion where a depth of a semiconductor stack in FIG. 2 being 0 μm to 0.5 μm.

FIG. 4 to FIG. 9 show performance simulation results of a semiconductor laser element of the disclosure.

FIG. 10 shows a relationship diagram of doping concentration, ion intensity, and depth of partial elements of a portion where a depth of a semiconductor stack depth of a semiconductor laser element provided by Embodiment 1 being 0.4 μm to 1 μm.

FIG. 11 shows a locally enlarged schematic diagram of a portion where a depth of the semiconductor stack depth in FIG. 10 is 0.6 μm to 0.7 μm.

### DESCRIPTION OF THE EMBODIMENTS

The following describes the implementation of the disclosure through specific embodiments. Those skilled in the art may easily understand other advantages and effects of this disclosure from the content disclosed in this specification. The disclosure may also be implemented or applied through other different specific embodiments, and various details in this specification may also undergo various modifications or changes based on different viewpoints and applications without departing from the spirit of the disclosure. It should be noted that, in the absence of conflict, the following embodiments and features in the embodiments may be combined with each other.

According to an aspect of the disclosure, provided is a semiconductor laser element including a semiconductor stack. The semiconductor stack includes a first semiconductor layer, a first wave guide layer, an active layer, a second wave guide layer, and a second semiconductor layer stacked sequentially from bottom to top. The first semiconductor layer is an N-type doped layer. The second semiconductor layer is a P-type doped layer. In a direction away from the active layer, the second semiconductor layer is sequentially provided with an electron barrier layer and a second coating layer. In the electron barrier layer, a P-type dopant has at least one doping concentration peak. The doping concentration of the P-type dopant at the doping concentration peak is less than the maximum doping concentration of the P-type dopant in the second semiconductor layer. Moreover, in a direction gradually approaching the electron barrier layer, the doping concentration of the P-type dopant in the second coating layer has multiple partitions. A doping concentration curve of the P-type dopant decreases partition by partition along the partitions.

Disposing a decreasing trend of Mg doping concentration in the second semiconductor layer may ensure that the second semiconductor layer provides sufficient holes, improves hole injection efficiency in a quantum well layer, and improves light-emitting efficiency. Meanwhile, disposing the second semiconductor layer may reduce absorption of light and improve a light exit effect of the device.

Optionally, in the direction gradually approaching the electron barrier layer, the doping concentration of the P-type dopant in the second coating layer shows a decreasing trend.

The doping concentration of the P-type dopant in the second coating layer may ensure the hole concentration on one side of the second semiconductor layer, thereby improving hole injection efficiency, which is beneficial to improving the light-emitting efficiency of a laser diode. The gradually decreasing doping concentration may effectively control the Mg diffusion depth of and prevent the Mg diffusion depth from affecting the light exit effect.

Optionally, on a side where the second coating layer adjoins the electron barrier layer, the doping concentration of the P-type dopant is less than the doping concentration of the P-type dopant of the doping concentration peak in the electron barrier layer.

The slight increase of Mg doping concentration in the electron barrier layer may provide additional barrier, effectively block electrons from overflowing the active region, and thereby improve the light-emitting efficiency and operating temperature range of the device.

Optionally, in the direction gradually approaching the electron barrier layer, the doping concentration of the P-type dopant in the second coating layer sequentially has a fourth partition, a third partition, a second partition, and a first partition. The doping concentration of the P-type dopant in the fourth partition lies between 8E18 atom/cm³ and 1E20 atom/cm³. The doping concentration of the P-type dopant in the third partition lies between 6E18 atom/cm³ and 8E18 atom/cm³. The doping concentration of the P-type dopant in the second partition lies between 3E18 atom/cm³ and 6E18 atom/cm³. The doping concentration of the P-type dopant in the first partition lies between 2E18 atom/cm³ and 4E18 atom/cm³.

Optionally, the doping concentration curve of the P-type dopant is in the first partition, the second partition, the third partition, and the fourth partition. The first partition has a minimum slope value, and the fourth partition has a maximum slope value.

Optionally, a range of a slope value of the second partition and a slope value of the third partition lies between 0.5E19 atom/cm³/μm and 6E19 atom/cm³/μm.

Optionally, the slope value of the second partition is greater than the slope value of the third partition.

Controlling the reduction of Mg doping concentration in the third partition is beneficial to lowering the impedance of series resistance, and simultaneously has the probability to activate more Mg to provide more holes, which improves the hole injection efficiency of the quantum well.

Optionally, a slope value of the first partition lies between 1E19 atom/cm³/μm and 4E19 atom/cm³/μm.

Optionally, a slope value of the fourth partition lies between 1E21 atom/cm³/μm and 9E21 atom/cm³/μm.

Controlling the concentration range and thickness range of the sharp decrease in the Mg doping concentration may reduce the unintentional doping of Mg in the active layer, which reduces the non-radiative recombination centers in the active layer, reduces the non-radiative recombination in the active layer, and improves the quantum efficiency of the laser.

Optionally, a thickness of the first partition lies between 0.05 μm and 0.3 μm. On the side adjoining the electron barrier layer, the doping concentration of the P-type dopant in the first partition is 3E18 atom/cm³±10%.

Setting the thickness of the first partition is helpful for the diffusion of holes, which reduces the diffusion depth of holes, and ensures sufficient holes in the active layer to undergo radiative recombination with electrons.

Optionally, a thickness of the second partition lies between 0.05 μm and 0.3 μm. A thickness of the third partition lies between 0.05 μm and 0.4 μm.

Optionally, a thickness of the fourth partition lies between 0.01 μm and 0.05 μm.

Optionally, the thickness of the first partition is less than the thickness of the second partition, and is also less than the thickness of the third partition.

The thickness of the second partition and the thickness of the third partition being greater than the thickness of the first partition is beneficial for improving the manufacturing yield of ridges in subsequent laser diodes, thereby being beneficial for improving the overall yield of laser diodes. Through setting the thickness of the second partition and the thickness of the third partition and setting the decrease rate of the Mg doping concentration, it is ensured that there is a probability to activate more Mg to provide more holes, which improves the hole injection efficiency of the quantum well.

Optionally, the doping concentration of the P-type dopant in the electron barrier layer lies between 1E18 atom/cm³ and 1E19 atom/cm³.

Optionally, after the P-type dopant enters the second wave guide layer from the electron barrier layer, the doping concentration of the P-type dopant decreases to below 1E18 atom/cm³.

The slight increase of the Mg doping concentration in the electron barrier layer may provide additional barriers to effectively block electrons from overflowing the active region, thereby improving the light-emitting efficiency and operating temperature range of the device. Additionally, the subsequent continuous decrease of the Mg doping concentration in the electron barrier layer helps to lower the barrier for hole injection, thereby improving the hole injection efficiency and further enhancing the performance of the device.

Optionally, a thickness of the second semiconductor layer lies between 250 nm and 500 nm. A thickness of the electron barrier layer lies between 5 nm and 10 nm. A thickness of the second coating layer lies between 200 nm and 400 nm.

Setting the thickness of each material layer ensures the optical performance of the laser element, for example, providing sufficient hole recombination efficiency, while reducing the absorption of light by the material layers and improving the light exit effect.

Optionally, the P-type dopant is magnesium element.

Optionally, a light-emitting wavelength of the active layer lies between 440 nm and 470 nm or between 505 nm and 540 nm.

In another aspect of the disclosure, provided is a light-emitting device including the semiconductor laser element according to the disclosure.

The composition and dopants of each layer included in the semiconductor laser element of the disclosure may be analyzed by any suitable method, for example, a secondary ion mass spectrometer (SIMS). The thickness of each layer included in the semiconductor laser element according to the disclosure may be analyzed by any suitable method, for example, a transmission electron microscopy (TEM) or a scanning electron microscope (SEM), for matching the depth positions of each layer on the SIMS spectrum.

In the disclosure, unless specifically stated otherwise, the term “peak shape” refers to a line profile including two line segments having slopes with opposite signs to each other, that is, a slope of one line segment is positive and a slope of another line segment is negative. The term “doping concentration peak” refers to the highest concentration value between the two line segments having slopes with opposite signs in the peak shape.

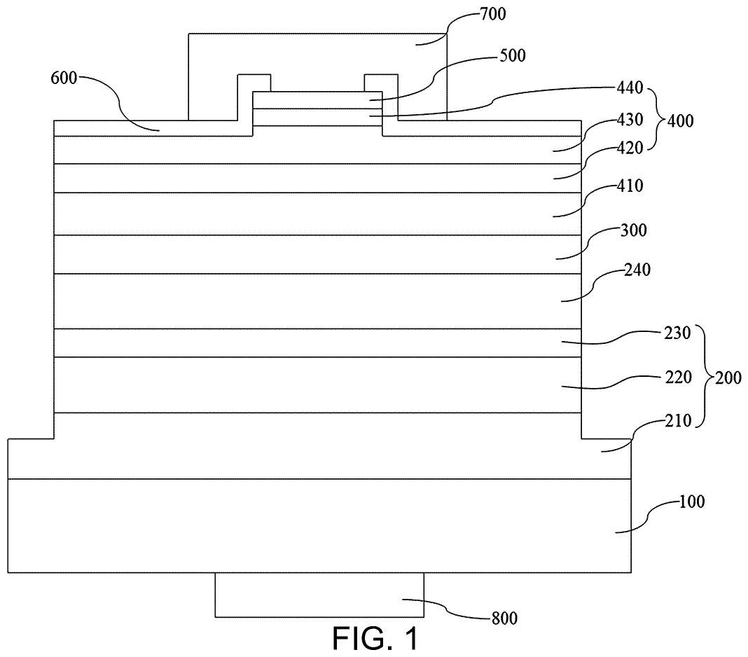

For convenience, the growth direction of the semiconductor stack is defined as upward, and the opposite direction is downward. As shown in FIG. 1, provided is a semiconductor laser element in this embodiment. The semiconductor laser element includes a semiconductor stack. The semiconductor stack includes a first semiconductor layer 200, a first wave guide layer 240, an active layer 300, a second wave guide layer 410, and a second semiconductor layer 400 stacked sequentially from bottom to top. The first semiconductor layer 200 in this embodiment is an N-type semiconductor layer. The second semiconductor layer 400 is a P-type semiconductor layer. The semiconductor laser element is an end-face light-emitting laser element, having a light emission end face and a light reflection end face that intersect with a main surface of semiconductor layers such as the active layer 300. The semiconductor stack has a ridge with a mesa structure at the top. The ridge is formed in the second coating layer 430 of the second semiconductor layer 400 and above regions. An extension direction of the ridge is a propagation direction of the laser. An insulating layer 600 is disposed on the side surfaces of the ridge and on the surface of the second semiconductor layer 400 continuous from the side surfaces of the ridge.

Optionally, as shown in FIG. 1, the aforementioned semiconductor laser element may further include a substrate 100. The substrate 100 has an upper surface and a lower surface opposite to each other. A first electrode 800 is disposed on a lower surface of the substrate 100. The first electrode 800 forms electrical connection with the first semiconductor layer 200. Additionally, a contact electrode 500 is disposed on an upper surface of the ridge. The contact electrode 500 forms an ohmic contact with the second semiconductor layer 400. The semiconductor laser element further includes a second electrode 700 disposed on an upper surface of the contact electrode 500. The second electrode 700 forms electrical connection with the contact electrode 500. The first electrode 800 and the second electrode 700 act together on a PN junction. Through the combination of electrons and holes, energy is released and photons are generated. The photons form a laser beam after reflection and amplification by the resonant cavity, thereby achieving the laser emission function of the laser diode.

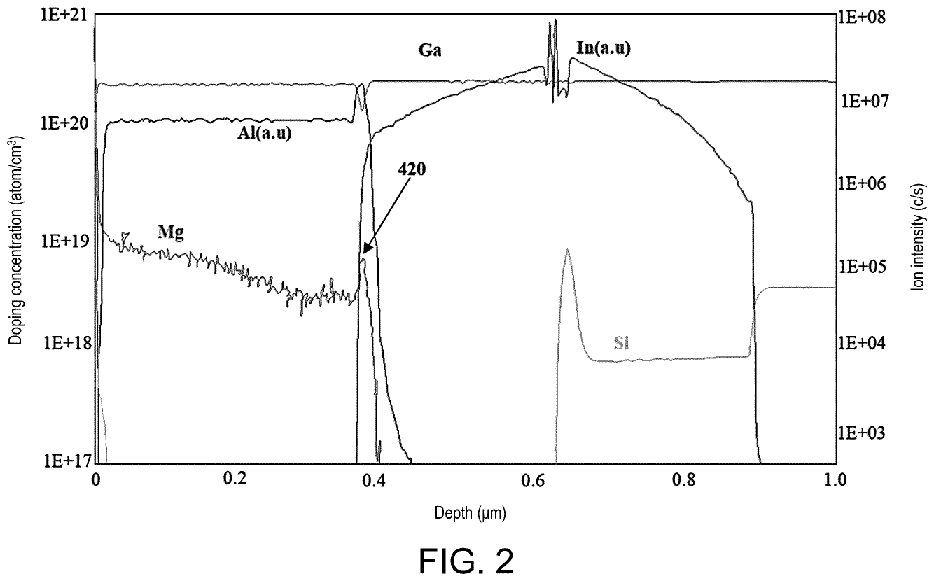

Referring to FIG. 1 and FIG. 2 continuously, the substrate 100 may be a growth substrate, including but not limited to a nitride semiconductor, SiC, or a high-impedance substrate such as a sapphire substrate. The substrate including the nitride semiconductor may improve heat dissipation efficiency due to higher thermal conductivity than sapphire, thereby reducing defects such as dislocations and achieving good crystallinity. In an optional embodiment, the substrate 100 may be a support substrate. The growth substrate originally used for epitaxial growth of the semiconductor stack may be selectively removed according to application requirements, and then the semiconductor stack is transferred to the aforementioned support substrate. Further, a thickness of the substrate 100 lies between 40 μm and 400 μm, for example, 50 μm, 80 μm, 100 μm, 150 μm, 200 μm, or 300 μm.

As shown in FIG. 1, the first wave guide layer 240 is formed below the active layer 300. The first semiconductor layer 200 is formed below the first wave guide layer 240. In a direction (toward the lower part of FIG. 1) gradually away from the active layer 300, the first semiconductor layer 200 includes a first coating layer 220 and a buffer layer 210 stacked on the substrate 100. The first semiconductor layer 200 may also be configured with other layers besides the above layers, and additionally, some layers may be omitted. For example, in an optional embodiment, in order to reduce lattice defects caused by mismatch of lattice constant, a stress release layer or similar structure may also be formed between the first wave guide layer 240 and the active layer 300.

As shown in FIG. 1, the second wave guide layer 410 is formed above the active layer 300. The P-type second semiconductor layer 400 is formed above the second wave guide layer 410. The second semiconductor layer 400 may be formed as a single layer structure or a multilayer structure formed by nitride material layers. As a p-type nitride semiconductor layer, the second semiconductor layer 400 may include, for example, a semiconductor material layer formed by nitride materials including p-type impurities such as Mg and C. For example, the second semiconductor layer 400 may be an AlGaInN material layer. In this embodiment, the P-type dopant of the second semiconductor layer 400 is Mg element. The Mg doping concentration lies between 1E18 atom/cm³ and 1E20 atom/cm³. Also referring to FIG. 1, in this embodiment, in the direction (toward the upper part of FIG. 1) gradually away from the active layer 300, the second semiconductor layer 400 includes an electron barrier layer 420 and a second coating layer 430 stacked sequentially. The second semiconductor layer 400 may also be configured with other layers besides the above layers, for example, an Ohmic contact layer 440 formed above the second coating layer 430, or some material layers may also be omitted.

As shown in FIG. 1, the second wave guide layer 410 is disposed adjacent to the active layer 300. A material of the second wave guide layer 410 may be InGaN. A thickness of the second wave guide layer 410 lies between 50 nm and 500 nm. Further, the thickness of the second wave guide layer 410 lies between 100 nm and 250 nm. The thickness setting of the second wave guide layer 410 may achieve a balance between carrier injection efficiency, refractive index, and layer structure strength. The addition of In component in the second wave guide layer 410 may enable the second wave guide layer 410 to have a higher refractive index to form a contrast with a refractive index of the active layer 300, thereby limiting the propagation path of light and enabling light to propagate within the wave guide layer, so as to achieve directional emission of light. Additionally, the addition of In component in the second wave guide layer 410 and the adjustment of the content may also effectively suppress electron leakage, increase hole injection, and facilitate improving the electron-hole recombination efficiency within the active layer 300.

As also shown in FIG. 1, an electron barrier layer 420 is formed above the second wave guide layer 410. A second coating layer 430 is formed above the electron barrier layer 420. A material of the electron barrier layer 420 may be a wide bandgap material such as AlN or AlGaN or AlInGaN, to effectively block electrons from leaking in the active layer 300 toward the second semiconductor layer 400, while allowing holes to pass through. The second wave guide layer 410 and the electron barrier layer 420 work synergistically in the laser device to jointly achieve confinement of optical field and carriers, which helps to more effectively recombine electrons and holes within the active region, to improve light-emitting efficiency. A material of the second coating layer 430 may be a wide bandgap material such as AlGaN. The second coating layer 430 limits light propagation within the wave guide layer by providing a lower refractive index than the second wave guide layer 410. A thickness of the second coating layer 430 lies between 100 nm to 500 nm, and further lies between 300 nm to 350 nm, to provide sufficient carrier diffusion toward the active layer 300. Meanwhile, the thickness should not be too thick to avoid excessive series resistance.

Referring to FIG. 2, the Mg doping concentration in the second semiconductor layer 400 lies between 1E18 atom/cm³ and 1E21 atom/cm³. The Mg doping concentration in the electron barrier layer 420 has at least one doping concentration peak. The Mg doping concentration at the doping concentration peak is less than the maximum Mg doping concentration in the second semiconductor layer 400. Optionally, the Mg doping concentration in the electron barrier layer 420 lies between 3E18 atom/cm³ and 8E18 atom/cm³. As shown in FIG. 2, the maximum Mg doping concentration in the second semiconductor layer 400 lies between 1E19 atom/cm³ and 1E21 atom/cm³. The Mg doping concentration at the concentration peak of Mg in the electron barrier layer 420 is obviously less than the above maximum Mg doping concentration in the second semiconductor layer 400. The concentration setting of Mg in the electron barrier layer 420 makes strict control of the Mg doping concentration within the range from the electron barrier layer 420 to the active layer 300, so that after Mg enters the second wave guide layer 410 from the electron barrier layer 420, the Mg doping concentration decreases to below 1E18 atom/cm³. As described above, controlling the diffusion of Mg toward the active layer 300 helps to reduce a non-radiative center related to Mg defects in the active region 300 so as to suppress a trap-assisted tunneling current, thereby improving the performance of the diode.

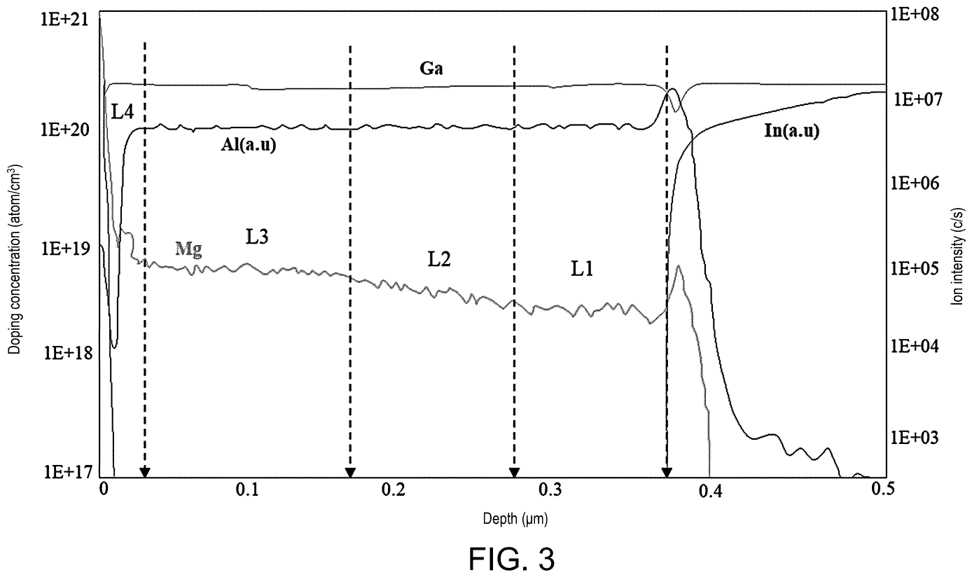

In an optional embodiment, as shown in FIG. 2 and FIG. 3, in the second semiconductor layer 400, along a direction gradually approaching the electron barrier layer 420, the Mg doping concentration in the second coating layer 430 presents an overall decreasing trend. The overall slope value of the doping curve lies between 2E18 atom/cm³/μm and 4E18 atom/cm³/μm. In an optional embodiment, during the process of overall decrease in the Mg doping concentration, a phenomenon of slight increase in the Mg doping concentration may occur within an extremely small thickness range. Further, the Mg doping concentration on a side of the second coating layer 430 adjacent to the electron barrier layer 420 is less than the Mg doping concentration at the Mg doping concentration peak in the electron barrier layer 420. Near the surface of the second semiconductor layer 400 on a side away from the active layer 300, that is, near a surface of the ohmic contact layer 440, the Mg doping concentration is maximum, greater than 1E19 atom/cm³, further, greater than 1E20 atom/cm³ and less than 1E21 atom/cm³. The high concentration of Mg doping in the ohmic contact layer 440 may improve the hole concentration in the second semiconductor layer 400, thereby reducing the contact resistance with metal contact. Moreover, the barrier height of metal-semiconductor contact may be reduced, which helps to achieve better ohmic contact. Additionally, the high concentration of Mg doping may increase the number of holes in the second semiconductor layer 400, thereby improving hole injection efficiency, which is beneficial for improving the light-emitting efficiency of the laser diode.

In an optional embodiment, in the direction gradually approaching the electron barrier layer 420, the Mg doping concentration curve in the second coating layer 430 may be divided into multiple partitions with different variation trends. The partitions of the Mg doping concentration curve have different slopes, that is, in the direction approaching the electron barrier layer 420, the Mg doping concentration in the second coating layer 430 gradually decreases overall, but the decrease magnitude or concentration variation magnitude of the Mg doping concentration within different partitions is not the same. For example, in the direction approaching the electron barrier layer 420, the Mg doping concentration in the second coating layer 430 may continuously present a decreasing trend, or based on an overall decreasing trend, some regions may have phenomena where the Mg doping concentration remains substantially unchanged or increases slightly.

In a specific embodiment of this embodiment, as shown in FIG. 3, in the direction gradually approaching the electron barrier layer 420, the Mg doping concentration curve of the second coating layer 430 has a fourth partition L4, a third partition L3, a second partition L2, and a first partition L1 sequentially. From the fourth partition L4 to the first partition L1, the Mg doping concentration gradually decreases overall. Specifically, the Mg doping concentration of the fourth partition L4 lies between 1E19 atom/cm³ and 1E20 atom/cm³, the Mg doping concentration of the third partition L3 lies between 6E18 atom/cm³ and 1E19 atom/cm³, the Mg doping concentration of the second partition L2 lies between 3E18 atom/cm³ and 6E18 atom/cm³, and the Mg doping concentration of the first partition L1 lies between 2E18 atom/cm³ and 4E18 atom/cm³. After Mg enters the electron barrier layer 420 from the second coating layer 430, the Mg doping concentration exhibits a sharp rise, followed by a sharp drop, to form at least one doping concentration peak in the electron barrier layer 420. As described above, the Mg doping concentration at this concentration peak is higher than the Mg doping concentration of the first partition L1 adjacent to the electron barrier layer 420, but lower than the Mg doping concentration of the fourth partition L4.

The doping concentration curve of the P-type dopant has a first slope, a second slope, a third slope, and a fourth slope in the first partition L1, the second partition L2, the third partition L3, and the fourth partition L4 respectively. The first slope has the minimum slope value, while the fourth slope has the maximum slope value. It should be noted here that in the second coating layer 430, the Mg doping concentration exhibits an overall decreasing trend. Therefore, the slopes of the doping curve are all negative values, with a negative sign indicating a direction of the doping curve. For convenience, only the numerical values (that is, slope values) after removing the negative sign are compared here, where a larger numerical value indicates a faster decreasing rate, and a smaller numerical value indicates a slower decreasing rate.

Specifically, referring to FIG. 3, a thickness of the first partition L1 lies between 0.05 μm and 0.3 μm, and further between 0.05 μm and 0.15 μm. The thickness setting of the first partition L1 helps the diffusion of holes, reduces the diffusion depth of holes, and ensures sufficient holes in the active layer 300 to undergo radiative recombination with electrons. Within the thickness range of the first partition L1, a slope value of the Mg doping concentration curve lies between 0.5E19 atom/cm³/μm and 2E19 atom/cm³/μm. Combined with FIG. 3, it may be seen that on the side adjacent to the electron barrier layer 420 and on the side adjacent to the second partition L2, the Mg doping concentration of the first partition L1 is approximately within a range of (3±0.5)E18 atom/cm³. Between the electron barrier layer 420 and the second partition L2, the Mg doping concentration exhibits a wave-like variation between 2.5E18 atom/cm³ and 3.5E18 atom/cm³. That is, within the range of the first partition L1, the variation trend of the Mg doping concentration gradually becomes gentle, always fluctuating within a small range around 3E18 atom/cm³.

Similarly combining FIG. 2 and FIG. 3, a thickness of the second partition L2 lies between 0.05 μm and 0.3 μm, and further lies between 0.09 μm and 0.2 μm. A thickness of the third partition L3 lies between 0.05 μm and 0.4 μm, and further between 0.12 μm and 0.3 μm. In an optional embodiment, the thickness of the second partition L2 is greater than the thickness of the first partition L1, and the thickness of the third partition L3 is also greater than the thickness of the first partition L1. The thicknesses of the second partition L2 and the third partition L3 being greater than the thickness of the first partition L1 is beneficial for improving the manufacturing yield of ridges in subsequent laser diodes, thereby being beneficial for improving the overall yield of laser diodes.

In an optional embodiment, in the second partition L2 and the third partition L3, the Mg doping concentration has a similar decreasing trend. As shown in FIG. 3, the overall slope value of the second partition L2 and the third partition L3 lies between 0.5E19 atom/cm³/μm and 6E19 atom/cm³/μm. Through the thickness setting of the second partition L2 and the third partition L3 and the decrease rate setting of the Mg doping concentration, it is ensured that there is a probability to activate more Mg to provide more holes, thereby improving the hole injection efficiency of the quantum well.

In a further optional embodiment, as shown in FIG. 3, a slope value of the second partition L2 lies between 1E19 atom/cm³/μm and 6E19 atom/cm³/μm, a slope value of the third partition L3 lies between 0.5E19 atom/cm³/μm and 4E19 atom/cm³/μm, and the slope value of the second partition L2 is greater than the slope value of the third partition L3. With the control mentioned above, the Mg doping concentration of the second partition L2 closer to the active layer 300 decreases faster, which is beneficial for reducing the impedance of series resistance. At the same time, there is a probability to activate more Mg to provide more holes to improve the hole injection efficiency of the quantum well.

Similarly as shown in FIG. 2 and FIG. 3, a thickness of the fourth partition L4 lies between 0.01 μm to 0.05 μm, and further lies between 0.02 μm and 0.05 μm. In the fourth partition L4, the Mg doping concentration drops sharply from 1E21 atom/cm³ and 1E19 atom/cm³. A slope of the fourth partition L4 lies between 1E22 atom/cm³/μm and 1E23 atom/cm³/μm, that is, the Mg doping concentration decreases significantly within the fourth partition L4. By controlling the concentration range and thickness range where the Mg doping concentration decreases sharply, the unintentional doping of Mg in the active layer 300 may be reduced, which reduces the non-radiative recombination center in the active layer 300, reduces non-radiative recombination in the active layer 300, and thus improves the quantum efficiency of the laser device.

Referring again to FIG. 3, a thickness of the electron barrier layer 420 lies between 0.05 μm and 0.2 μm, and further lies between 0.1 μm and 0.15 μm. In the electron barrier layer 420, the Mg doping concentration lies between 1E18 atom/cm³ to 1E19 atom/cm³ and forms a doping concentration peak. That is, after Mg enters the electron barrier layer 420 from the first partition, the Mg doping concentration may first increase, then decrease sharply, and form a doping concentration peak. After this value of the doping concentration peak, in the direction entering the second wave guide layer 410 and the active layer 300, the Mg doping concentration decreases significantly. After Mg enters the second wave guide layer 410, the Mg doping concentration decreases to below 1E18 atom/cm³, and further decreases to below 1E17 atom/cm³. The increase of the Mg doping concentration in the electron barrier layer 420 may improve the hole concentration of the electron barrier layer 420, which enhances the blocking effect on electrons, effectively blocks electrons from overflowing the active region 300, and thus improves the light-emitting efficiency of the device. In addition, the Mg doping concentration in the electron barrier layer 420 continues to decrease, which helps to reduce the barrier for hole injection, thereby improving the hole injection efficiency and further enhancing the performance of the device.

Setting the thicknesses and the Mg doping concentration s of the second coating layer 430 and the electron barrier layer 420 makes the side of the second semiconductor layer 400 to provide sufficient holes to the active layer 300. Moreover, unintentional doping of impurities such as Mg, C, H, O in the active layer 300 is reduced, especially reducing unintentional doping of Mg and C therein, which reduces the non-radiative recombination center in the active layer 300, reduces non-radiative recombination in the active layer 300, and thus improves the quantum efficiency of the laser device. The efficiency of the laser device is reduced.

In an optional embodiment, an ohmic contact layer 440 may also be formed above the second coating layer 430. A material of the ohmic contact layer 440 may be GaN or InGaN, which matches the lattice constant of the second coating layer 430. The Mg doping concentration in the ohmic contact layer 440 is relatively high, for example, between 1E20 atom/cm³ and 1E21 atom/cm³. Through high doping, the conductivity may be improved, which reduces the resistance in contact with the metal electrode, forms good ohmic contact, and reduces the voltage value of the laser diode to promot uniform current injection.

In an embodiment of the disclosure, the semiconductor laser element may form a ridge by etching part of the second semiconductor layer 400. The width of the ridge may be adjusted to 1 μm to 5 μm. A contact electrode 500 is disposed on an upper surface of the ridge. Specifically, the main function of the contact electrode 500 is to improve lateral expansion capability and expand the region portion where the current acts. A material of the contact electrode 500 may adopt transparent conductive films such as indium tin oxide (ITO), indium zinc oxide (IZO), zinc oxide (ZnO), and gallium oxide (GaO₃). A material of the contact electrode 500 may also adopt metals such as nickel and gold. The contact electrode 500 is a transparent conductive film having a refractive index smaller than the refractive index of the active layer 300. Further, an insulating layer 600 is formed on an exposed side surface of the ridge, the side surface of the contact electrode 500, and the surface of the second coating layer 430 exposed through etching. A film thickness of the insulating layer 600 lies between 100 nm and 500 nm. The insulating layer 600 may be formed by a single-layer film or a multi-layer film of materials such as oxides or nitrides of Si, Al, Zr, Ti, Nb, and Ta.

Also referring to FIG. 1, the active layer 300 is located between the first semiconductor layer 200 and the second semiconductor layer 400. Specifically, the active layer 300 is located between the first wave guide layer 240 and the second wave guide layer 410. The active layer 300 may be set as a multi-layer structure formed by a nitride semiconductor such as GaN and InGaN. The active layer 300 has a single quantum well structure or a multiple quantum well structure. In a case where the active layer 300 includes a multiple quantum well structure, if barrier layers and well layers are alternately stacked, the starting layer and the terminating layer may be either well layers or barrier layers. Further, the multiple quantum well structure includes 2 to 15 pairs of alternately arranged barrier layers and well layers. In an optional embodiment, the thickness of each barrier layer in the active layer 300 may be the same or different, and the thickness of each well layer may also be the same or different.

Further, for semiconductor laser elements that emit blue-green light, the well layers and barrier layers in the active layer 300 include InGaN/GaN material layers. The light-emitting wavelength of the semiconductor laser element may be controlled by adjusting the In content of the well layers to make the semiconductor laser element emit blue light or green light. Optionally, the output wavelength of the laser diode may be tested through an integrating sphere test method. In this embodiment, the measured output wavelength range of the laser diode lies between 440 nm and 540 nm, more specifically, between 440 nm and 470 nm, or between 505 nm and 540 nm.

Referring to FIG. 1 continuously, the first semiconductor layer 200 is an AlGaInN material layer. For example, the first semiconductor layer 200 may be set as a multi-layer structure formed by a nitride semiconductor such as GaN, InGaN, and AlGaN. The first semiconductor layer 200 includes a first coating layer 220 and an electron providing layer 230 sequentially stacked on the substrate 100. In an optional embodiment, in order to improve the lattice quality of the epitaxial stack, a buffer layer 210 may also be formed between the substrate 100 and the first coating layer 220.

In an optional embodiment, the first semiconductor layer 200 may further be formed with an electron providing layer 230. The electron providing layer 230 is located between the first coating layer 220 and the first wave guide layer 240. The electron providing layer 230 may be an AlGaN material layer. By adjusting the refractive index and thickness of the first coating layer 220, optical field confinement may be achieved, which makes light mainly concentrated between the wave guide layers of the laser device, and thereby improves the efficiency and performance of the laser device. The first coating layer 220 requires a certain thickness to effectively confine carriers and prevent electron overflow. Typically, the thickness of the first coating layer 220 lies between 100 nm and 500 nm.

In an optional embodiment, the n-type doping concentration of the electron providing layer 230 is greater than or equal to 3×10¹⁸ atom/cm³, which effectively increases electron injection efficiency and improves carrier recombination efficiency in the active layer 300. A thickness of the electron providing layer 230 is less than or equal to 500 nm. Specifically, the thickness of the electron providing layer 230 lies between 10 nm and 100 nm, preferably between 10 nm and 50 nm, and the doping concentration lies between 2×10¹⁸ atom/cm³ and 1.5×10¹⁹ atom/cm³. The n-type impurity doping concentration of the electron providing layer 230 is typically greater than the n-type impurity doping concentration of the first coating layer 220. It may be understood that since laser in the wave guide layer causes gain coefficient to decrease due to doping, which affects carrier recombination efficiency and luminous brightness, the insertion of the electron providing layer 230 may effectively inject electrons from the first coating layer 220 into the active layer 300, thereby accumulating sufficient non-equilibrium electron concentration in the well layers of the active layer 300, so that the quantity and distribution of electrons within the active layer 300 are optimized, and the quantum efficiency of the laser device is improved. Additionally, the electron providing layer 230 may further limit electron diffusion in the horizontal direction, reduce electron overflow, reduce non-radiative recombination of carriers, and ensure the electrons are mainly concentrated in the active region, thereby improving the efficiency of the laser device.

In the aforementioned embodiment, the thickness of the electron providing layer 230 is less than a thickness of the first wave guide layer 240, ensuring good optical confinement capability and also providing a relatively flat surface as a growth foundation for the first wave guide layer 240, which is beneficial for improving the crystal quality of the first wave guide layer 240. The thickness of the electron providing layer 230 lies between 10 nm and 30 nm, for example, 10 nm, 15 nm, 20 nm, 25 nm, or 30 nm. An excessively thick layer may lead to introduction of more defects or stress during subsequent material deposition processes, affecting the reliability and stability of the device. Moreover, the excessively thin thickness may not withstand stress or temperature changes in subsequent processes, leading to layer structure cracking or failure, and higher precision is required for doping processes. Furthermore, the thickness of the electron providing layer 230 lies between 15 nm and 25 nm, for example 20 nm, to achieve a good balance between electron providing capability and layer structure quality.

In the aforementioned embodiment, the electron providing layer 230 is a GaN material with high Si element doping. The doping concentration of the electron providing layer 230 is greater than the doping concentrations of the first coating layer 220 and the first wave guide layer 240. By setting a higher Si doping concentration, electron concentration is improved to ensure sufficient carrier recombination in the active layer 300. Furthermore, in the growth direction of the thickness of the semiconductor stack, the Si element doping in the electron providing layer 230 is uniform, with the initial doping concentration of the lower surface to the doping concentration of the upper surface remaining substantially consistent. The constant doping concentration is beneficial for simplifying the preparation process and also enables the electron concentration in the electron providing layer 230 to remain stable, which may improve the performance stability of the semiconductor laser element.

As shown in FIG. 1, the first wave guide layer 240 is located between the electron providing layer 230 and the active layer 300. A material of the first wave guide layer 240 may be InGaN. By introducing different proportions of In components in InGaN, the refractive index and band gap of the wave guide layer are adjusted, so that the refractive index of the first wave guide layer 240 is higher than the refractive index of the first coating layer 220. The first wave guide layer 240 works synergistically with the second wave guide layer 410, so that light is confined to propagate within the wave guide layers, achieving effective optical gain effects. Meanwhile, the electron providing layer 230 below the first wave guide layer 240 may also play a certain role in reducing electron overflow. The thickness of the first wave guide layer 240 lies between 50 nm and 500 nm to achieve a balance among electron injection efficiency, refractive index, and layer structure strength. Furthermore, the thickness of the first wave guide layer 240 is close to the thickness of the second wave guide layer 410, both of which lie between 50 nm and 500 nm. Further, the thickness of the first wave guide layer 240 lies between 200 nm to 400 nm. In an optional embodiment, as shown in FIG. 2, the content of In component in the first wave guide layer 240 gradually increases as approaching the active layer 300, which improves electron-hole recombination efficiency.

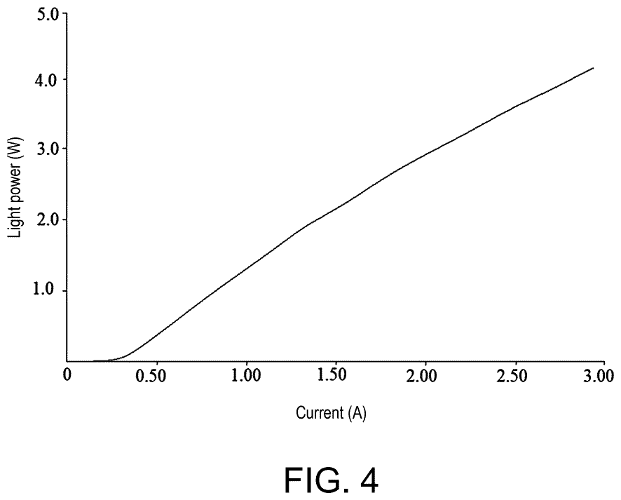

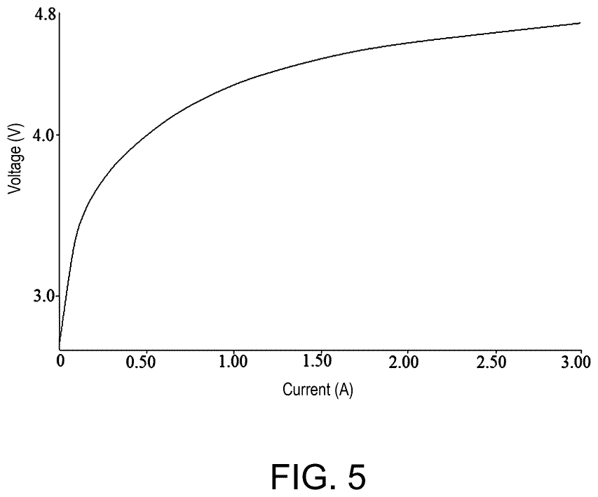

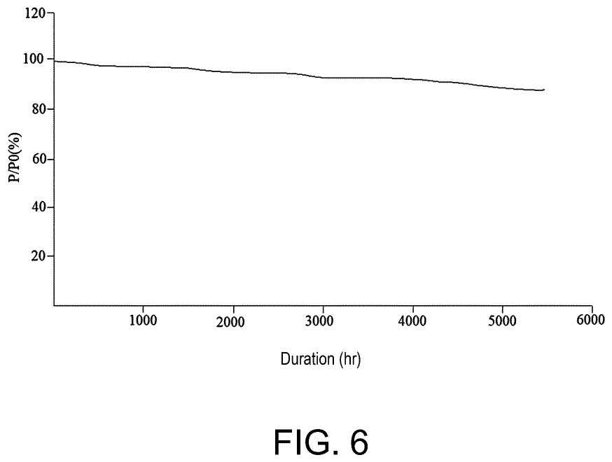

In order to verify the related performance of the laser diode having the second semiconductor layer 400 with the doping characteristics of this embodiment, photoelectric performance simulation was conducted. As shown in FIG. 4 to FIG. 6, P-I and V-I simulation curve diagrams and lifetime simulation results of blue light and green light of laser diodes having the second semiconductor layer 400 are respectively shown. As shown in FIG. 4 to FIG. 6, in the simulation of the blue light of the laser diode, an output light wavelength is defined as to about 450 nm, a ridge width RW of the laser diode is 30 μm, and a length L of the resonant cavity is 1200 μm. From the P-I and V-I curves of the blue light of the laser diode, it may be seen that a threshold current Ith of the blue light of the laser diode having the aforementioned second semiconductor layer structure is approximately 300 mA, a threshold current density Jth is approximately 0.83 kA/cm², and a rate at which the power of the laser diode increases with current, that is, a slope efficiency SE is approximately 1.55W/A. From a duration-P/P0 curve of the blue light of the laser diode, it may be seen that after continuous operation for 6000 hours, a percentage of the change in optical output power (P) of the blue light of the laser diode with time (hours) relative to the initial power (P0) remains above 85%.

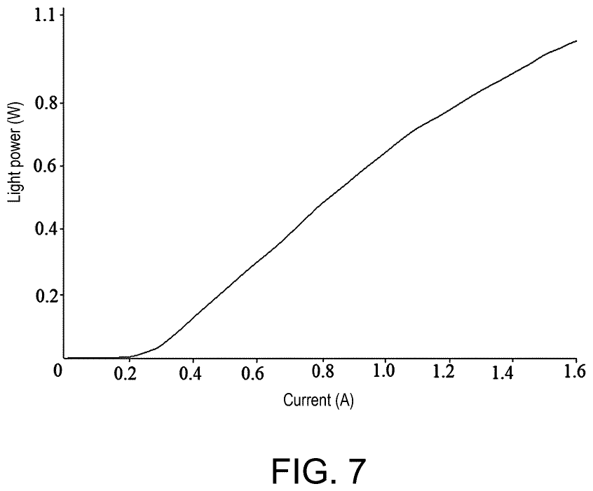

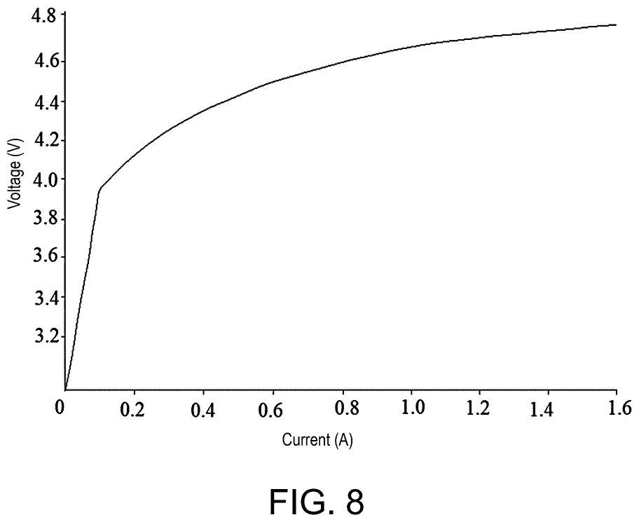

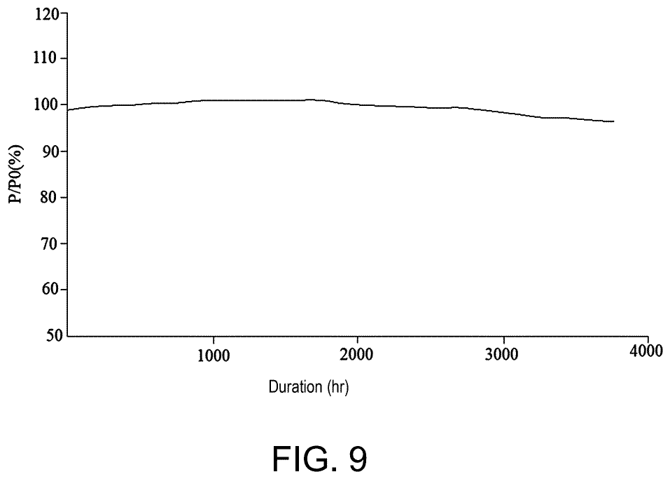

As shown in FIG. 7 to FIG. 9, in the simulation of the green light of the laser diode, an output light wavelength is defined as to about 515 nm, a ridge width RW of the laser diode is 15 μm, and a length L of the resonant cavity is 1200 μm. From the P-I and V-I curves of the green light of the laser diode, it may be seen that a threshold current Ith of the green light of the laser diode having the aforementioned second semiconductor layer structure is approximately 300 mA, a threshold current density Jth is approximately 1.66 kA/cm², and a rate at which the power of the laser diode increases with current, that is, a slope efficiency SE is approximately 0.72W/A. From a duration-P/P0 curve of the green light of the laser diode, it may be seen that after continuous operation for 4000 hours, a percentage of the change in optical output power (P) of the green light of the laser diode with time (hours) relative to the initial power (P0) remains above 95%.

From the aforementioned simulation results, it may be seen that the laser diode having the second semiconductor layer 400 of this embodiment has a lower threshold current and good photoelectric conversion efficiency. Meanwhile, with the change of time, the laser diode has small power attenuation and good stability. The device has higher service lifespan and high reliability.

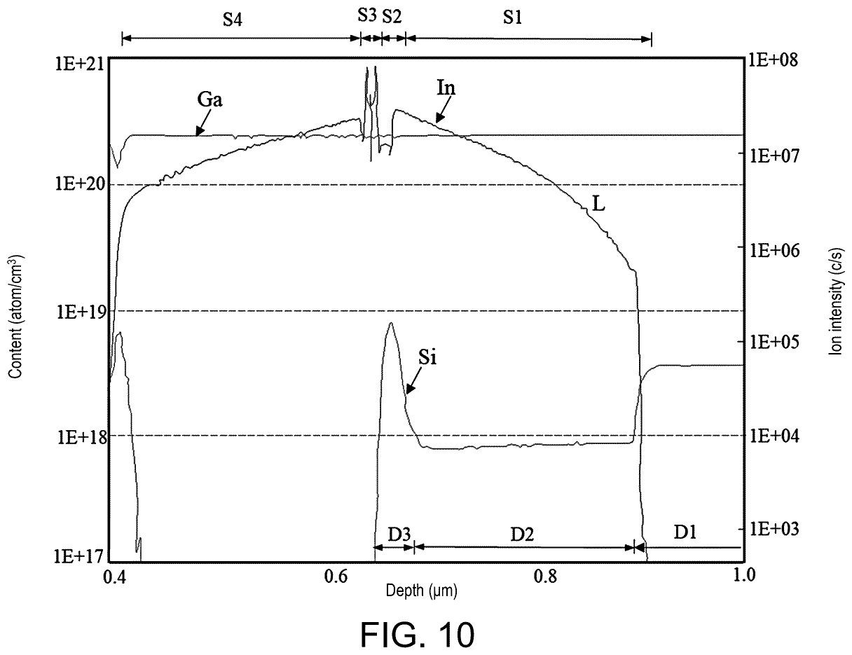

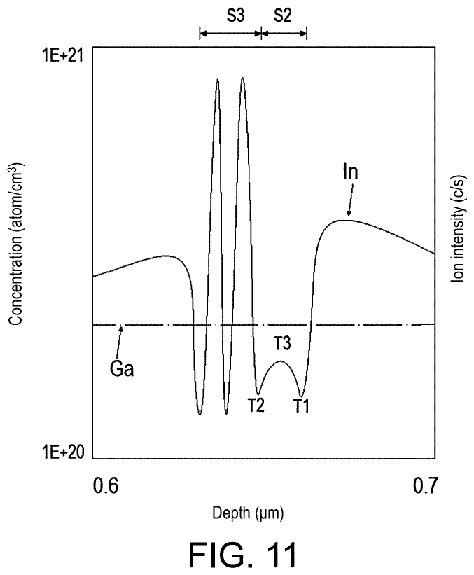

As shown in FIG. 10 and FIG. 11, within the range from the first wave guide layer 240 to the second wave guide layer 410, the In component has an ion intensity curve. The ion intensity curve includes a first portion S1, a second portion S2, a third portion S3, and a fourth portion S4 connected in sequence. The In component ion intensity of the first portion S1 gradually increases in the direction from the first wave guide layer to the second wave guide layer and reaches a maximum value at the connection with the second portion S2. The second portion S2 includes a first valley T1, a second valley T2, and a middle section T3 located between the first valley T1 and the second valley T2. The ion intensity of the middle section T3 is greater than the ion intensity of the first valley T1 and greater than the ion intensity of the second valley T2. The first valley T1 is connected to the first portion S1. The second valley T2 is connected to the third portion S3. The In component ion intensity of the third portion S3 has two significant peaks. At the connection with the third portion S3, the initial intensity of the In component ion intensity of the fourth portion S4 is the maximum value and gradually decreases in the direction from the first wave guide layer 240 to the second wave guide layer 410.

Similarly, as shown in FIG. 10 and FIG. 11, the In component ion intensity of the second portion S2 is smaller than the maximum ion intensity of the In component in the first portion S1, the In component ion intensity of the middle section T3 of the second portion S2 is smaller than the maximum ion intensity of the fourth portion S4, and thereby the carrier overflow phenomenon caused by excessively high In component content of the middle section T3 is avoided. Specifically, for the second portion S2, the In ion intensity of the middle section T3 is greater than the In ion intensity of the first valley T1 and the In ion intensity of the second valley T2. The semiconductor material corresponding to the middle section T3 may be, for example, InGaN. The valleys on both sides contain a small amount of In component or do not contain In component. The semiconductor material corresponding to the valleys on both sides may be, for example, GaN. It may be understood that a signal duration length of the In component ion intensity corresponds to the thicknesses of different semiconductor layers to a certain extent. A layer thickness of the first portion S1 is greater than a layer thickness corresponding to the second portion S2. For the second portion S2, a layer thickness of the middle section T3 is greater than a layer thickness corresponding to the first valley T1, and is also greater than a layer thickness corresponding to the second valley T2.

In this embodiment, the first wave guide layer 240 corresponds to the first portion S1 of an ion intensity curve L shown in FIG. 1. The thickness of the first wave guide layer 240 corresponding to the first portion S1 lies between 50 nm and 500 nm to achieve a balance among electron injection efficiency, refractive index, and layer structure strength. Further, the thickness of the first wave guide layer 240 lies between 200 nm and 400 nm.

Through experiments, under a condition that parameters of other semiconductor layer are the same, when an In content percentage of the active layer is 10% and the maximum In content percentages of the first wave guide layer 240 and the second wave guide layer 410 are within a range of 2% to 10%.

It may be understood that for semiconductor laser devices of other wavelengths, the light-emitting wavelength may be adjusted by adjusting the In content in the active layer 300, thereby achieving light emission of different colors. Taking the green light of the semiconductor laser element as an example, a green light wavelength is greater than a blue light wavelength, and the In content in the active layer 300 is also relatively high. In order to confine light between the wave guide layers, the difference in refractive indexes between the wave guide layer and the coating layer should also be large. Therefore, the In content in the wave guide layer is also relatively high compared to the In content in the blue light of the semiconductor laser device.

Referring to FIG. 2 and FIG. 10 continuously, it may be seen that the Si element has a concentration curve along the direction from the first semiconductor layer 200 to the active layer. The concentration curve includes a first section D1, a second section D2, and a third section D3 connected in sequence. The first section D1 corresponds to a region of the first semiconductor layer 200 away from the active layer 300. The third section D3 corresponds to a region of the first semiconductor layer 200 adjoining the active layer 300. A concentration value of the second section D2 is lower than a concentration value of the first section D1. The Si element has a peak concentration in the third section D3. The concentration of the first section D1 is smaller than the peak concentration. The Si doping concentration in the first section D1 lies between 9×10¹⁷ atom/cm³ and 4×10¹⁸ atom/cm³, so as to effectively increase electron injection efficiency and improve the quantum efficiency of the laser device.

In an embodiment, the peak concentration of the third section D3 is smaller than or equal to 1E19 atom/cm³. The third section D3 is a semiconductor layer approaching the active layer 300, limiting the peak concentration thereof and avoiding defects brought to the crystal by excessively high doping concentration. It may be understood that by optimizing the distribution of Si element, the third section D3 may have more than one peak concentration to optimize the performance of the semiconductor laser element. In an alternative embodiment, when the third section D3 corresponds to multiple stacked structures of different material compositions, for example a GaN/InGaN/GaN multilayer structure. The doping peak concentration may occur in any semiconductor layer corresponding to the third section D3.

In the aforementioned embodiment, the first section D1 may be an AlGaN material with high Si element doping. The doping concentration of the first section D1 lies between 9×10¹⁷ atom/cm³ and 4×10¹⁸ atom/cm³. By inserting the highly doped first section D1 before the second section D2, to provide sufficient electron concentration, electron-hole recombination efficiency is improved, and thereby luminous brightness is enhanced. The concentration of the second section D2 lies between 5×10¹⁷ atom/cm³ and 2×10¹⁸ atom/cm³. The doping concentration of the third section D3 lies between 1×10¹⁸ atom/cm³ and 9×10¹⁸ atom/cm³. The third section D3 has relatively high Si doping concentration to reduce the influence of polarization field on carrier recombination efficiency in the active layer 300.

In the aforementioned embodiment, the semiconductor layer, namely the electron providing layer 230, corresponding to the first section D1 has Si concentration smaller than the Si peak concentration in the third section D3. Moreover, along the direction from the first semiconductor layer 200 to the active layer, Si element is uniformly doped in the electron providing layer 230. The initial doping concentration of the lower surface of the electron providing layer 230 to the doping concentration of the upper surface of the electron providing layer 230 remains basically consistent. The constant doping concentration is beneficial to simplifying the preparation process, and also makes the electron concentration in the electron providing layer 230 remain stable, which may improve the performance stability of the semiconductor laser element. By inserting the electron providing layer 230, the quantity and distribution of electrons within the active layer 300 are optimized, and the quantum efficiency of the laser device is improved. The doping concentration of intra-layers lies between 1×10¹⁸ atom/cm³ and 4×10¹⁸ atom/cm³, to provide sufficient electrons to the quantum well layer for effective recombination. In an alternative embodiment, the doping concentration of the first section D1 may also be uniform gradient doping or graded gradient doping.

In an alternative embodiment, as shown in FIG. 1, the aforementioned semiconductor laser element further includes a first electrode 800 and a second electrode 700. The second electrode 700 is formed on the ridge, contacts the contact electrode 500, and thereby is electrically connected to the second semiconductor layer 400. A thickness of the second electrode 700 lies between 0.1 μm and 2 μm. Generally, any thickness that may function as an electrode of the semiconductor laser element is acceptable. A material of the second electrode 700 may be metals or alloys such as Ni, Rh, Cr, Au, W, Pt, Ti, and Al. The first electrode 800 is disposed on the lower surface of the substrate 100, and is electrically connected to the first semiconductor layer 200. A material of the first electrode 800 includes any one or combination of two or more of Ni, Ti, Pd, Pt, Au, Al, TiN, ITO, and IGZO, but the disclosure is not limited thereto.

### Embodiment 2

In this embodiment, a light-emitting device is provided. The light-emitting device includes a driving substrate and a light-emitting element fixed on the driving substrate. The light-emitting element may include the semiconductor laser element provided in Embodiment 1. Therefore, the light-emitting device also has the aforementioned excellent effects.

In summary, the semiconductor laser element and the light-emitting device provided by the disclosure effectively overcome various disadvantages in the prior art, and have high industrial utility value.

The aforementioned embodiments only exemplify the principles and effects of the disclosure, and are not used to limit the disclosure. Any person familiar with this technology may modify or change the aforementioned embodiments without violating the spirit and scope of the disclosure. Therefore, all equivalent modifications or changes completed by those skilled in the art without departing from the spirit and technical concept disclosed by the disclosure should still be covered by the claims of the disclosure.

What is claimed is:

1. A semiconductor laser element, comprising:
a semiconductor stack,
the semiconductor stack comprising: a first semiconductor layer, a first wave guide layer, an active layer, a second wave guide layer, and a second semiconductor layer stacked sequentially from bottom to top,
wherein,
the first semiconductor layer is an N-type doped layer,
the second semiconductor layer is a P-type doped layer,
in a direction away from the active layer, the second semiconductor layer is sequentially provided with an electron barrier layer and a second coating layer;
in the electron barrier layer, a P-type dopant has at least one doping concentration peak,
a doping concentration of the P-type dopant at the doping concentration peak is less than a maximum doping concentration of the P-type dopant in the second semiconductor layer, and,
in a direction gradually approaching the electron barrier layer, a doping concentration of the P-type dopant in the second coating layer has a plurality of partitions, and a doping concentration curve of the P-type dopant decreases partition by partition along the plurality of partitions.

2. The semiconductor laser element according to claim 1, wherein,
in a direction gradually approaching the electron barrier layer, a doping concentration of the P-type dopant in the second coating layer shows a decreasing trend.

3. The semiconductor laser element according to claim 1, wherein,
the second coating layer adjoins a side of the electron barrier layer,
a doping concentration of the P-type dopant is less than the doping concentration of the P-type dopant at the doping concentration peak in the electron barrier layer.

4. The semiconductor laser element according to claim 1, wherein,
in a direction gradually approaching the electron barrier layer, the doping concentration of the P-type dopant in the second coating layer sequentially has a fourth partition, a third partition, a second partition, and a first partition,
wherein,
a doping concentration of the P-type dopant in the fourth partition lies between 8E18 atom/cm³ and 1E20 atom/cm³,
a doping concentration of the P-type dopant in the third partition lies between 6E18 atom/cm and 8E18 atom/cm³,
a doping concentration of the P-type dopant in the second partition lies between 3E18 atom/cm³ and 6E18 atom/cm³, and
a doping concentration of the P-type dopant in the first partition lies between 2E18 atom/cm³ and 4E18 atom/cm³.

5. The semiconductor laser element according to claim 4, wherein,
doping concentration curves of the P-type dopant are in the first partition, the second partition, the third partition, and the fourth partition,
wherein
the first partition has a minimum slope value, and
the fourth partition has a maximum slope value.

6. The semiconductor laser element according to claim 4, wherein,
a range of a slope value of the second partition and a slope value of the third partition lies between 0.5E19 atom/cm³/μm and 6E19 atom/cm³/μm.

7. The semiconductor laser element according to claim 6, wherein,
the slope value of the second partition is greater than the slope value of the third partition.

8. The semiconductor laser element according to claim 4, wherein,
a slope value of the first partition lies between 0.5E19 atom/cm³/μm and 2E19 atom/cm³/μm.

9. The semiconductor laser element according to claim 4, wherein,
a slope value of the fourth partition lies between 1E21 atom/cm³/μm and 9E21 atom/cm³/μm.

10. The semiconductor laser element according to claim 4, wherein,
a thickness of the first partition lies between 0.05 μm and 0.3 μm, and
on a side adjoining the electron barrier layer, the doping concentration of the P-type dopant in the first partition is 3E18 atom/cm³±10%.

11. The semiconductor laser element according to claim 4, wherein,
a thickness of the second partition lies between 0.05 μm and 0.3 μm, and
a thickness of the third partition lies between 0.05 μm and 0.4 μm.

12. The semiconductor laser element according to claim 4, wherein,
a thickness of the fourth partition lies between 0.01 μm and 0.05 μm.

13. The semiconductor laser element according to claim 4, wherein,
a thickness of the first partition is smaller than a thickness of the second partition, and is also smaller than a thickness of the third partition.

14. The semiconductor laser element according to claim 1, wherein,
a doping concentration of the P-type dopant in the electron barrier layer lies between 1E18 atom/cm³ and 1E19 atom/cm³.

15. The semiconductor laser element according to claim 1, wherein,
after entering the second wave guide layer from the electron barrier layer, the doping concentration of the P-type dopant decreases to below 1E18 atom/cm³.

16. The semiconductor laser element according to claim 1, wherein,
a thickness of the second semiconductor layer lies between 250 nm and 500 nm,
a thickness of the electron barrier layer lies between 5 nm and 10 nm, and
a thickness of the second coating layer lies between 200 nm and 400 nm.

17. The semiconductor laser element according to claim 1, wherein,
the P-type dopant is a magnesium element.

18. The semiconductor laser element according to claim 1, wherein,
a light-emitting wavelength of the active layer lies between 440 nm and 470 nm, or between nm and 540 nm.

19. A light-emitting device, comprising:
the semiconductor laser element according to claim 1.
